(19) United States
(12) Patent Application Publication
(10) Pub. No.: US 2002/0014402 A1
(43) Pub. Date: Feb. 7, 2002

(54) Sputtering system, sputtering support system and sputtering control method

(76) Inventors: Yoshihiko Nagamine, Hitachi (JP); Yoshiya Higuchi, Naka (JP); Tadashi Sato, Mito (JP); Tomoyuki Seino, Hitachi (JP); Mitsuhiro Kamei, Takahagi (JP)

Correspondence Address: MATTINGLY, STANGER & MALUR, P.C., 104 East Hume Avenue, Alexandria, VA, 22301, US

(21) Appl. No.: 09/791,617

(22) Filed: Feb. 26, 2001

(30) Foreign Application Priority Data
Jul. 5, 2000 (JP) 2000-208227

(51) Int. Cl. C23C 14/34

(52) U.S. Cl. 204/192.13; 204/192.12; 204/298.03; 204/298.08

(57) ABSTRACT

The present invention is characterized by; detecting the volume of impurities in said vacuum vessel wherein plasma is generated by radio frequency power supplied to the target electrode and substrate electrode, and a target is sputtered by ions in said plasma, thereby forming films on the substrate, and controlling the phase difference of radio frequency power supplied to each of said electrodes according to said detection value.

### BACKGROUND OF THE INVENTION

1. Field of the Invention

The present invention relates to the sputtering method as one of most commonly used thin film forming methods, and particularly to sputtering system, sputtering support system and sputtering control method based on radio frequency power source (hereinafter referred to as “RF”).

2. Related Background Art

In the sputtering system, voltage is applied between the target electrode and substrate electrode, and plasma is generated in the vacuum vessel. In this case, an ion sheath is formed between plasma and substrate. Sputter gas such as argon gas introduced into the vacuum vessel becomes ions in plasma, and is accelerated by the electric field of the sheath. Then the accelerated ions collide with the target to sputter it, and the sputtered target is deposited on the substrate to form a thin layer.

In the sputtering system on the other hand, the inside of the vacuum vessel is often released to the atmosphere for incoming or outgoing of the substrate or for maintenance work. It is widely known that moisture will deposit on the wall inside the vessel in this case, making film formation rate unstable.

To solve this problem, an attempt is made to measure the concentration of water in the vessel and to control the RF power applied to the target electrode based on the result of measurements. For example, the Official Gazette of Japanese Patent Laid-Open NO. 72307-1995 (hereinafter referred to as “known example”) discloses a method of measuring the concentration of residual moisture by atmospheric release and controlling the sputtering power in conformance to measurements.

In the invention disclosed in the above-mentioned known example, however, the effective power of the RF power source is changed according to the concentration of residual moisture in order to control the sputtering power. This results in the problem of causing change of power consumption.

### SUMMARY OF THE INVENTION

An object of the present invention, therefore, is to provide a sputtering system, sputtering support system and sputtering control method which ensure a constant film formation rate without changing power consumption.

This invention has been reached through the following findings gained by the authors of the present invention:

Residual moisture is decomposed into hydrogen gas and hydrogen ions by plasma. As a result, not only the argon gas contributing to sputtering but also hydrogen ions are accelerated by RF power. Then part of RF power is used by hydrogen ions, and the energy of argon ions is reduced by that used amount. However, almost no sputtering occurs despite collision of hydrogen ions, and this reduces the number of the targets to be sputtered; hence, reduction of film formation rate, according to the finding of the authors of the present invention.

Since the present invention was made against the background shown above, it is characterized by;

detecting the volume of impurities in said vacuum vessel wherein plasma is generated by radio frequency power supplied to the target electrode and substrate electrode, and a target is sputtered by ions in said plasma, thereby forming films on the substrate, and

controlling the phase difference of radio frequency power supplied to each of said electrodes according to said detection value.

The present invention maintains a constant energy of argon ions contributing to sputtering without power consumption being changed. This makes it possible to maintain a fixed film formation rate.

### BRIEF DESCRIPTION OF THE DRAWINGS

FIG. 1 is a schematic configuration representing the first Embodiment of the sputtering system according to the present invention;

FIG. 2 is a process flow chart in the first Embodiment of the sputtering system according to the present invention;

FIG. 3 is a diagram representing the relationship between the output voltage of the quadrupole mass spectrometer and the current value of hydrogen ions flowing to the target in the first Embodiment of the sputtering system according to the present invention;

FIG. 4 is a diagram representing the relationship between the current value of hydrogen ions flowing to the target and film formation rate in the first Embodiment of the sputtering system according to the present invention;

FIG. 5 is a diagram representing the relationship between the reduction of film formation rate and the increase/decrease of RF power phase difference in the first Embodiment of the sputtering system according to the present invention;

FIG. 6 is a diagram representing the target electrode voltage, substrate electrode voltage, vacuum vessel wall surface voltage and plasma potential for one cycle when RF power phase difference is zero deg. in the first Embodiment of the sputtering system according to the present invention;

FIG. 7 is a diagram representing the sheath voltage for one cycle when RF power phase difference is zero deg. in the first Embodiment of the sputtering system according to the present invention;

FIG. 8 is a diagram representing the target electrode voltage, substrate electrode voltage, vacuum vessel wall surface-voltage and plasma potential for one cycle when RF power phase difference is 45 deg. in the first Embodiment of the sputtering system according to the present invention;

FIG. 9 is a diagram representing the sheath voltage for one cycle when RF power phase difference is 45 deg. in the first Embodiment of the sputtering system according to the present invention;

FIG. 10 is a schematic configuration representing the second Embodiment of the sputtering system according to the present invention; and

FIG. 11 is a schematic configuration representing the third Embodiment of the sputtering system according to the present invention.

### DETAILED DESCRIPTION OF PREFERRED EMBODIMENTS

Embodiments of the present invention will be described with reference to Figures.

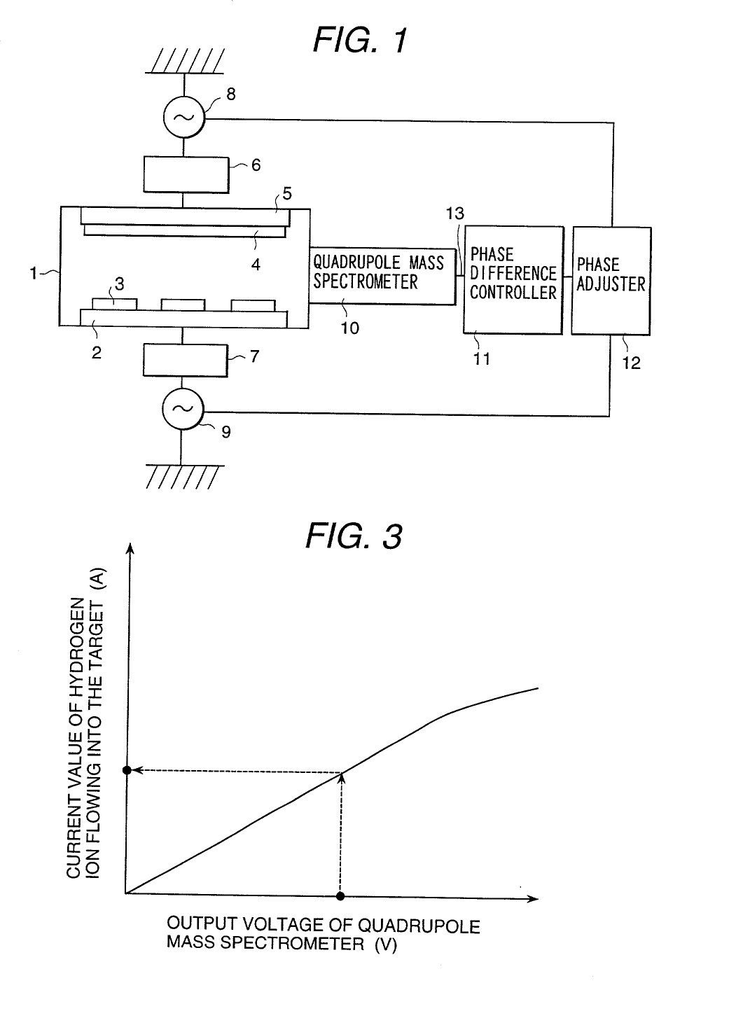

FIGS. 1 to 9 show the first Embodiment of the sputtering system according to the present invention.

As shown in FIG. 1, in the sputtering system according to this Embodiment, a target electrode 5 with a target 4 mounted thereon and a substrate electrode 2 with a substrate 3 mounted thereon are installed in the vacuum vessel. For example, when such a magnetic disk as hard disk drive is manufactured, such a magnetic substance as Co-Ni-Cr or such an insulator as Al₂O₃ is used as a target material, and Al₂O₃ is used as a substrate material. Further, argon gas can be sealed inside as discharge gas.

RF power is supplied to the target electrode 5 through the matching box on the arget side 6 by the RF power source on the target side 8. RF power is also supplied to the substrate electrode 2 from the RF power source on the substrate side 9 through the matching box on the substrate side 7.

The vacuum vessel 1 is equipped with a quadrupole mass spectrometer 10 to measure the concentration of hydrogen gas produced by decomposition of residual water by plasma. It is connected to a phase difference controller 11 through a signal line 13. Further, a phase difference controller 11 is connected to phase adjuster 12 through signal line 13. The phase adjuster 12 is connected to the RF power source on the target side 8 and RF power source on the substrate side 9 through the signal line 13.

In the sputtering system characterized by such a configuration as well, the method of forming a film on the substrate by sputtering the target through acceleration of argon ions to collide them with the target is the same as before.

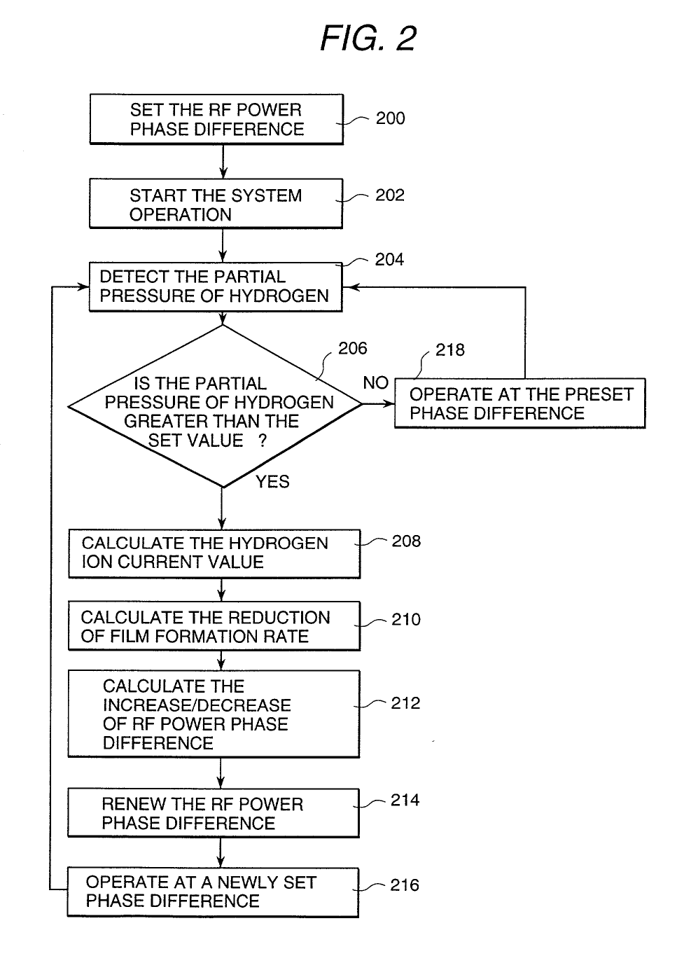

Using FIG. 2, the following describes how to control the phase difference of power supplied to the target electrode 5 and substrate electrode 2, based on the concentration of hydrogen gas detected by quadrupole mass spectrometer 10.

First, the phase difference of power supplied to the target electrode 5 and substrate electrode 2 is set to zero (S200).

When the RF power is supplied to each electrode to start operation of the sputtering system thereafter, moisture deposited inside the vacuum vessel is decomposed by plasma at the time of release into the atmosphere, resulting in increased volume of hydrogen gas and hydrogen ions (S202) The concentration of hydrogen gas is detected by the quadrupole mass spectrometer 10 (S204). The volume of hydrogen ions inside the vacuum vessel is changed according to the concentration of hydrogen gas. So it is sufficient to detect the concentration of hydrogen gas. The mass spectrometer 10 outputs the voltage value to the phase difference controller 11 according to the detected concentration.

The phase difference controller 11 first determines whether or not the voltage value input from the quadrupole mass spectrometer 10 exceeds the preset reference value (S206). For example, the voltage valve corresponding to hydrogen gas concentration of 5% is assumed as a reference value in the present Embodiment. If the reference valve is not reached, operation is continued with the-RF power phase difference kept at zero (S218). Conversely, if the voltage has exceeded the reference valve, a process starts to calculate the phase difference in conformance to the voltage value.

The following describes the details of the process of calculating the phase difference.

First, the phase difference controller 11 calculates the current value of hydrogen ions corresponding to the voltage value of the actually output quadrupole mass spectrometer from the relationship obtained by experiment or calculation in advance (S208).

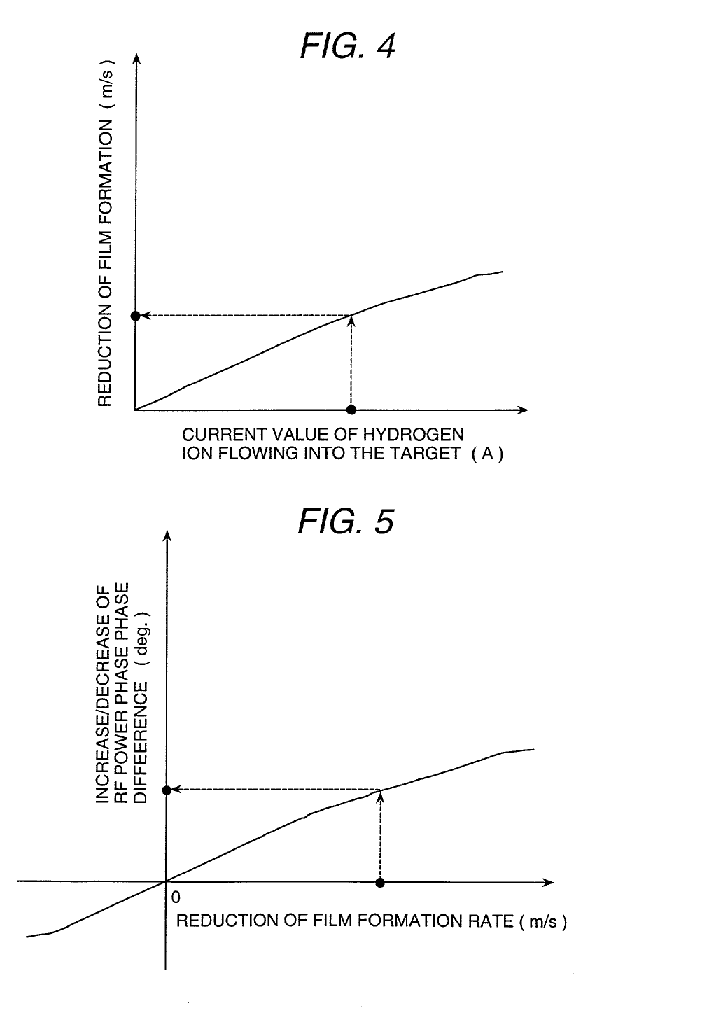

Then the reduction of the film formation rate corresponding to the current value of the hydrogen ions is calculated from the relationship shown in FIG. 4 obtained by experiment or calculation in advance (S210). The reduction of the film formation rate is assumed as the difference between the film formation rate without any hydrogen ion current and the film formation rate with consideration given to hydrogen ion current.

Lastly, increase or decrease of the RF power phase difference corresponding to the film formation rate is calculated from the relationship shown in FIG. 5 obtained by experiment or calculation in advance (S212).

Based on the increase or decrease of the RF power phase difference calculated from the above process, the RF power phase difference is output to the phase adjuster 12 (S214). The phase of the current RF power source on the target side 8, namely, the phase of RF power currently supplied to the target electrode 5, together with the RF power phase difference, is sent to the phase adjuster 12. What is sent from the phase adjuster 12 to RF power source on the substrate side 9 is the phase advanced or delayed the phase difference calculated by the phase difference controller 11, with the phase of the RF power source on the target side 8 as a reference(S216).

Based on that, RF power source on the substrate side 9 adjusts the RF power phase supplied to the substrate electrode 2. In the present Embodiment, RF power phase sent to each electrode is assumed as equal to each power source phase.

If there is an increase of hydrogen gas concentration after adjustment of the phase, the process again starts to calculate the phase difference in conformance to that concentration. It should be noted, however, that the relationship among the output voltage value of the quadrupole mass spectrometer, hydrogen ion current value flowing into the target, film formation rate reduction and increase/decrease of the RF power phase difference varies according to the RF power phase difference. Accordingly, the relationship in phase difference subsequent to change must be obtained by experiment or calculation. The same procedure is repeated after adjustment has been made to reach the calculated phase difference.

The above Embodiment provides following operations and effects:

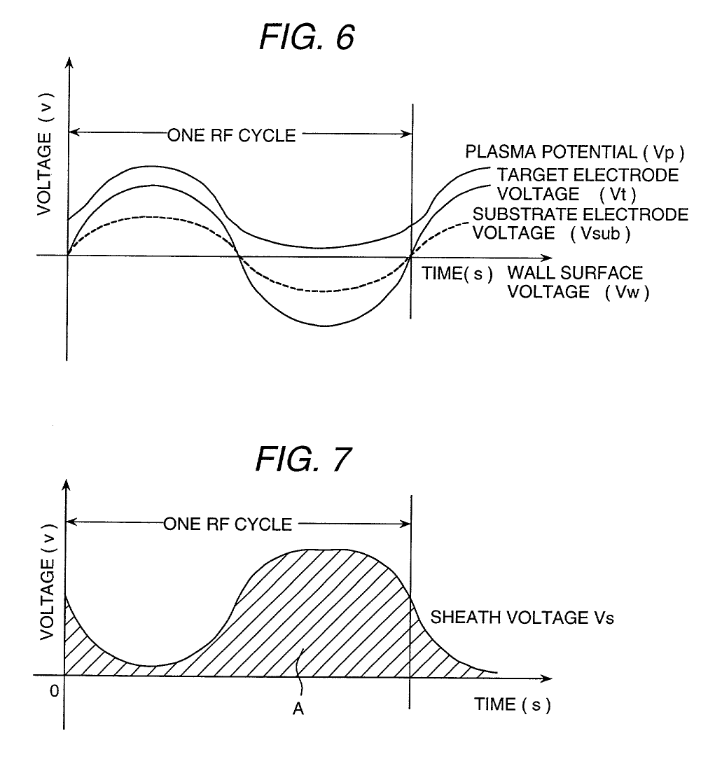

Assume that the difference between the phase of the RF power supplied to the target electrode and the phase of RF power supplied to the substrate electrode is zero deg. in the initial setup, as shown in FIG. 6. Plasma potential Vp is designed to take a value about 5 to 15 volts higher than the greatest of the target electrode voltage Vt, substrate electrode voltage Vsub and voltage Vw of the vacuum vessel wall surface (grounded). In this case, the voltage phase difference among electrodes is equal to the phase difference among RF powers supplied to electrodes.

Assume, in the meantime, that N cycles are required before its collision with the target subsequent to entry of ions into the sheath. Energy to be obtained in the entire process,

$$ϵ = N {\int }_{0}^{T} ⅆ t {\int }_{0}^{d} qE ( x , t ) ⅆ x \qquad ( 1 )$$

where T denotes a cycle, and q the value of electrical charge of the ions colliding with the target. E(x,t) represents the electric field of the sheath, and is a function of time t and position x. Further, sheath voltage Vs shows the difference between Vp and Vt, hence

$${\int }_{0}^{d} E ( x , t ) ⅆ x = Vs ( t ) \qquad ( 2 )$$

When equation (2) is incorporated into (1),

$$ϵ = N {\int }_{0}^{T} Vs ( t ) ⅆ t \qquad ( 3 )$$

It can be seen from (3) that the energy obtained before collision of ions with the target is proportional to the area (hatched portion A) created between the time axis and Vs in FIG. 7. The energy equivalent to the area of hatched portion A represents the energy obtained before collision of argon ion with the target.

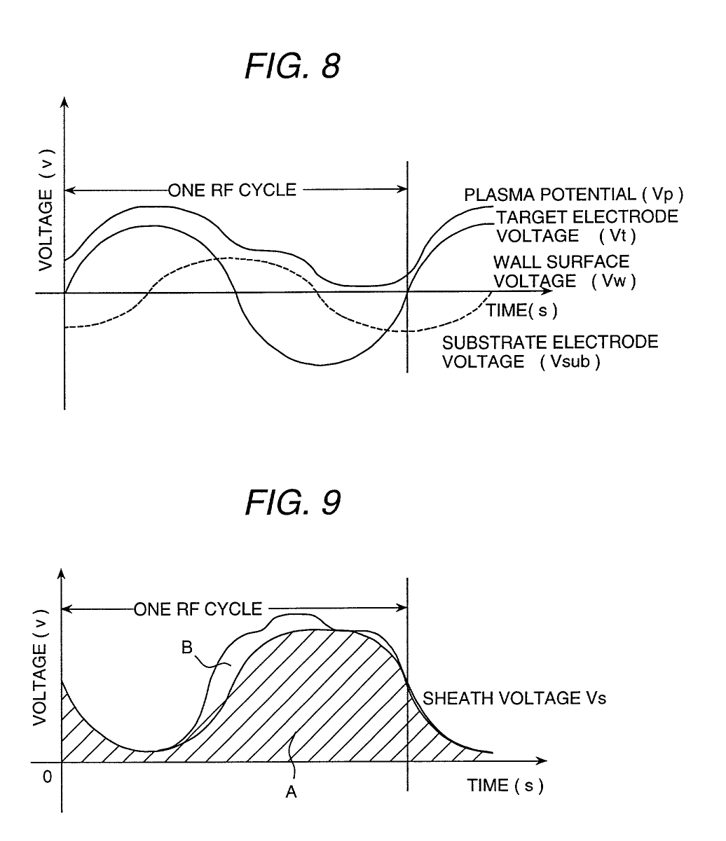

Assume that the phase difference of RF power is changed in response to increase of hydrogen gas and is set to 45 deg., for example, as shown in FIG. 8. Vp always takes a value greater than Vt, Vsub and Vw, hence the waveform of Vp is raised the shift of phase Accordingly, the development of Vs with respect to time is different from that when the phase difference of the RF power is zero deg., as shown in FIG. 9.

Further, the area (hatched portion A + white-out lettering portion) created between the time axis and Vs in FIG. 9 shows an increase over that in FIG. 7. This signifies an increase of energy of ions colliding with the target.

However, energy corresponding to the area of the hatched portion A plus white-out lettering portion in FIG. 9 is the sum of the energy gained before collision of argon, hydrogen or other ions with the target. Energy corresponding to white-out lettering portion B which is the increase from the area of FIG. 7 approximately represents the energy obtained by hydrogen ions. Namely, the energy of argon ions remains constant at the energy corresponding to the area of the hatched portion A in FIG. 7. This ensures that the energy of argon ions contributing to sputtering is retained constant.

Power phase difference is changed with the increase of hydrogen concentration in the present Embodiment, as discussed above. This makes it possible to maintain a constant film formation rate. Further, the root mean square value of the RF power supplies to electrodes are not changed; hence, no change in the consumption of RF power source.

Further, the effect of flattening the film on the substrate surface can also be expected by application of RF power to the substrate electrode as well.

In the present Embodiment, the initial setup value of the RF power phase difference is zero deg., but is not restricted to this value alone.

If the phase difference of RF powers supplied to electrodes is not equal to the phase difference among power supplies, it is sufficient that the phase difference among power supplies is calculated by the phase difference controller 11, with consideration given to it.

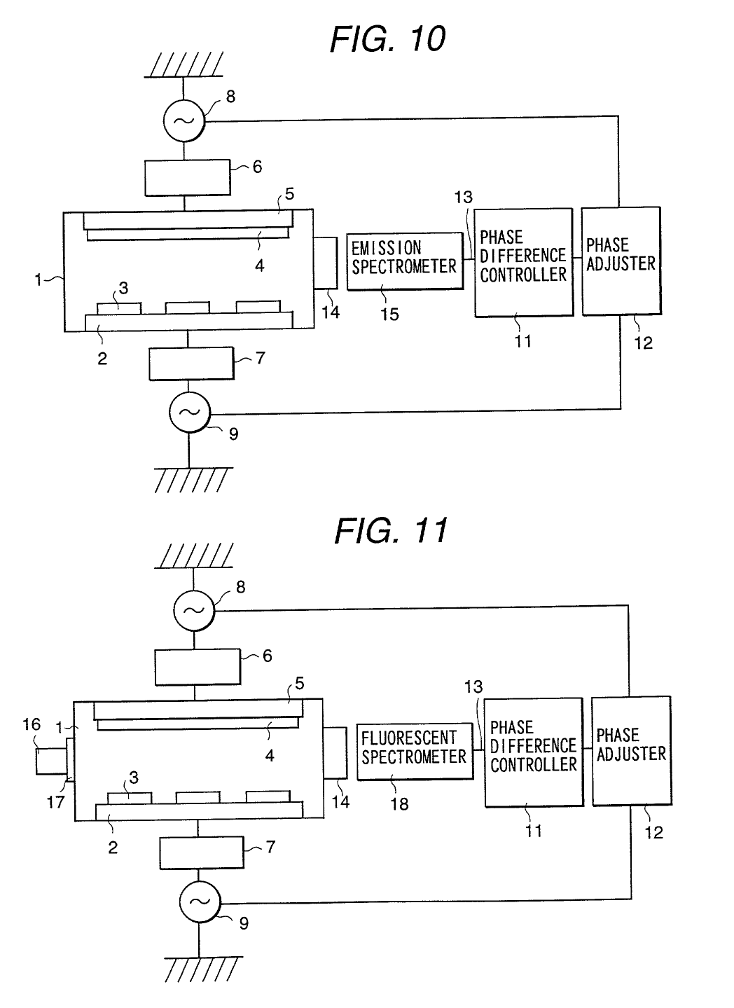

FIG. 10 is a drawing illustrating a second Embodiment according to the present invention.

The sputtering system in the present Embodiment has an observation sight 14 mounted on the vacuum vessel 1 of the first Embodiment. Further, the emission spectrometer 15 is installed instead of the quadrupole mass spectrometer 10.

According to the present Embodiment, light coming from within in the vacuum vessel is subjected to spectroscopy by the emission spectrometer 15 through the observation sight 14, and the voltage value in conformance to the volume of hydrogen ions is sent to the phase difference controller 10. Otherwise, phase difference is controlled in the same manner as in the first Embodiment. Furthermore, emission spectrometer 15 is not designed to directly measure the gas in the vacuum vessel 1. It can be installed away from the vacuum vessel 1, without disturbing the state of plasma. Furthermore, if only the vacuum vessel 1 is equipped with an observation sight 14, it can be mounted on the existing sputtering system without the possibility of vacuum leakage.

FIG. 11 is a drawing representing a third Embodiment according to the present invention.

The sputtering system in this Embodiment is provided with a fluorescent spectrometer 18 instead of the emission spectrometer 15 of the third Embodiment. Further, the incident port 17 and laser oscillator 16 are provided on the side opposing to the observation sight 14. Fluorescent spectrometer 18 allows the light having a wider range of wavelength to be detected than that of the emission. spectrometer 15.

Laser beam is emitted by the laser oscillator 16 into the vacuum vessel 1 through the incident port 1, to excite the molecular state. Light emitted when returning from the excited state to the basic state is subjected to spectroscopy by the fluorescent spectrometer 18, and voltage valve in conformance to hydrogen ions obtained by spectroscopy is sent to the phase difference controller 11. Otherwise, procedures are the same as those of Embodiment 3.

The following describes a fourth Embodiment according to the present invention:

This Embodiment represents a sputtering support system mounted on the vacuum vessel of the existing sputtering system. It consists of the quadrupole mass spectrometer 10 and phase difference controller 11 used in the first Embodiment connected with each other.

Assume, for example that the existing sputtering system comprises a vacuum vessel equipped with two electrodes inwardly opposed to each other, RF power supplies to feed RF power and a phase adjuster, wherein said phase adjuster serves to maintain the phase difference of each RF power source at the specified value during the operation of the sputtering system.

The quadrupole mass spectrometer 10 of the sputtering support system of this Embodiment is connected to the exhaust port for vacuum exhaustion inside the vacuum vessel of this sputtering system. In the meantime, the phase difference controller 11 is connected to the phase adjuster of the existing sputtering system to make it possible to specify the phase difference to be maintained, whenever required.

Use of the sputtering support system of this Embodiment provides the same effects as those of the first Embodiment. Further, it allows a direct use of the existing sputtering system, and permits an easy addition without changing the configuration.

Even if the phase adjuster is not used in the existing sputtering system, it is sufficient that a sputtering support system including the phase adjuster is mounted. Further, the emission spectrometer 15 or fluorescent spectrometer 18 can also be used in place of the quadrupole mass spectrometer 10.

In the Embodiments discussed above, hydrogen concentration is detected and the RF power phase difference is controlled in conformance to the detected value. It is also possible to change the energy of argon ion itself by changing the phase difference alone, independently of changes in hydrogen concentration. Namely, sputter rate and film formation rate can be changed as required by controlling the RF power phase difference.

It is also possible to control the phase difference by changing the phase of the RF power source on the target side 8 with reference to the phase of the RF power source on the substrate side 9, or by changing both the phase of the RF power source on the substrate side 9 and the phase of the RF power source on the target side 8.

Furthermore, use of a wider target causes an uneven potential on the target surface. So it is possible to divide the target electrode into multiple electrodes to permit supply from a single RF power source.

As discussed above, the present invention maintains a constant energy of argon ions contributing to sputtering without power consumption being changed. This makes it possible to maintain a fixed film formation rate.

What is claimed is:

1. A sputtering system comprising;
a vacuum vessel,
a target electrode installed in said vacuum vessel with a target mounted on said target,
a radio frequency power source on the target side to supply radio frequency power to said target electrode,
a substrate electrode installed in said vacuum vessel with a substrate mounted on said electrode,
a radio frequency power source on the substrate side to supply radio frequency power to said substrate electrode,
a detecting means to detect the volume of impurities in said vacuum vessel, and
a control means to control the phase difference of radio frequency power supplied to each of said electrodes according to the volume of impurities detected by said detecting means.

2. A sputtering system comprising;
a vacuum vessel,
a target electrode installed in said vacuum vessel with a target mounted on said target,
a radio frequency power source on the target side to supply radio frequency power to said target electrode,
a substrate electrode installed in said vacuum vessel with a substrate mounted on said electrode,
a radio frequency power source on the substrate side to supply radio frequency power to said substrate electrode,
a detecting means to detect the volume of hydrogen in said vacuum vessel,
a phase difference controller to calculate the phase difference of each of said radio frequency power supplies according to the volume of hydrogen detected by said detecting means, and
a phase adjuster to adjust at least one of the phases of said radio frequency power supplies using the phase difference calculated by said phase difference controller.

3. A sputtering system comprising;
a vacuum vessel,
a target electrode installed in said vacuum vessel with a target mounted on said target,
a radio frequency power source on the target side to supply radio frequency power to said target electrode,
a substrate electrode installed in said vacuum vessel with a substrate mounted on said electrode,
a radio frequency power source on the substrate side to supply radio frequency power to said substrate electrode,
a quadrupole mass spectrometer to detect the volume of hydrogen in said vacuum vessel,
a phase difference controller to calculate the phase difference of said radio frequency power supplies according to the volume of hydrogen detected by said quadrupole mass spectrometer, and
a phase adjuster to adjust and output the phase of said radio frequency power source on the substrate side to ensure that the phase difference of radio frequency power supplies will be the same as the phase difference calculated by said phase difference controller, wherein the phase of said radio frequency power source on the target side as well as the phase difference calculated by said phase difference controller are input into said phase adjuster.

4. A sputtering system according to claim 1 or 2;
said system has an emission spectrometer as said detecting means, and said emission spectrometer analyzes the light coming from the vacuum vessel to detect impurities through an observation sight installed on part of said vacuum vessel wall surface.

5. A sputtering system according to claim 1 or 2;
said system has an emission spectrometer as said detecting means, and a laser beam launching means to launch laser beam into said vacuum vessel;
wherein said emission spectrometer detects impurities by analyzing the light emitted when laser beam is launched into said vacuum vessel by said laser beam launching means, through an observation sight installed on part of said vacuum vessel wall surface.

6. A sputtering support system comprising;
a detecting means to detect the volume of impurities in the vacuum vessel wherein plasma is generated by radio frequency power supplied to the target electrode and substrate electrode, and a target is sputtered by ions in said plasma, thereby forming films on the substrate, and
a control means to control the phase difference of radio frequency power supplied to each of said electrodes according to the volume of impurities detected by said detecting means.

7. A sputtering support system comprising;
a detecting means to detect the volume of hydrogen inside the vacuum vessel wherein plasma is generated by radio frequency power supplied to the target electrode and substrate electrode, and a target is sputtered by ions in said plasma, thereby forming films on the substrate, and
a phase difference controller to calculate the phase difference of each of said radio frequency power supplies according to the volume of hydrogen detected by said detecting means.

8. A sputtering support system comprising;
a detecting means to detect the volume of hydrogen inside the vacuum vessel wherein plasma is generated by radio frequency power supplied to the target electrode and substrate electrode, and a target is sputtered by ions in said plasma, thereby forming films on the substrate,
a phase difference controller to calculate the phase difference of each of said radio frequency power supplies according to the volume of hydrogen detected by said detecting means, and
a phase adjuster to adjust at least one of said radio frequency power supplies using the phase difference calculated by said phase difference controller.

9. A sputtering support system comprising;
a quadrupole mass spectrometer to detect the volume of hydrogen in said vacuum vessel wherein plasma is generated by radio frequency power supplied to the target electrode and substrate electrode, and a target is sputtered by ions in said plasma, thereby forming films on the substrate,
a phase difference controller to calculate the phase difference of each of said radio frequency power supplies according to the volume of hydrogen detected by said quadrupole mass spectrometer, and
a phase adjuster to adjust and output the phase of said radio frequency power source on the substrate side to ensure that the phase difference of radio frequency power supplies will be the same as the phase difference calculate by said phase difference controller, wherein the phase of said radio frequency power source on the target side as well as the phase difference calculated by said phase difference controller are input into said phase adjuster.

10. A sputtering control method characterized by changing the energy of ion sputtering the target by controlling the phase difference of the radio frequency power supplied to said target electrode and substrate electrode.

11. A sputtering control method characterized by,
detecting the volume of impurities in said vacuum vessel wherein plasma is generated by radio frequency power supplied to the target electrode and substrate electrode, and a target is sputtered by ions in said plasma, thereby forming films on the substrate, and
controlling the phase difference of radio frequency power supplied to each of said electrodes according to said detection value.

12. A phase difference control method characterized by,
detecting the volume of impurities in said vacuum vessel wherein plasma is generated by radio frequency power supplied to the target electrode and substrate electrode, and a target is sputtered by ions in said plasma, thereby forming films on the substrate, and
comparing between said detection value and specified value to determine whether or not the phase difference of the current radio frequency power supplied to each of said electrodes should be maintained.

13. A phase difference control method characterized by,
detecting the volume of hydrogen in said vacuum vessel wherein plasma is generated by radio frequency power supplied to the target electrode and substrate electrode, and a target is sputtered by ions in said plasma, thereby forming films on the substrate,
calculating the phase difference each of said radio frequency power supplies according to said detection value, and
changing the phase of said radio frequency power source on the substrate side according to said phase-difference and the phase of said radio frequency power source on the target side.
